(19) United States
(12) Patent Application Publication
(10) Pub. No.: US 2003/0127682 A1
(43) Pub. Date: Jul. 10, 2003

(54) Non-volatile memory device having improved coupling ratio uniformity

(75) Inventors: Hun-Kook Lee, Kyunggi-do (KR); Sung-Nam Chang, Kyunggi-do (KR); Sung-Hoi Hur, Seoul (KR)

Correspondence Address: MARGER JOHNSON & McCOLLOM, P.C., 1030 S.W. Morrison Street, Portland, OR, 97205, US

(73) Assignee: Samsung Electronics Co., Ltd, Hwasung-city (KR)

(21) Appl. No.: 10/222,109

(22) Filed: Aug. 16, 2002

(30) Foreign Application Priority Data
Jan. 8, 2002 (KR) 2002-00965

(51) Int. Cl. H01L 29/788

(52) U.S. Cl. 257/315

(57) ABSTRACT

A NAND-type flash memory device is provided. The flash memory device comprises a plurality of word line patterns formed on the substrate. The total number of the word line patterns is N. The word line patterns are disposed parallel to a string selection line pattern. The word line patterns are disposed between the ground selection line pattern and the string selection line pattern in plan view, and comprises a first word line pattern, a Nth word line pattern and intermediate word line patterns. The first word line pattern is adjacent to the string selection line pattern. The Nth word line pattern is adjacent to the ground selection line pattern. The intermediate word line patterns are disposed between the first and Nth word line patterns in plan view. The first and Nth word line patterns are wider than the intermediate word line patterns.

This application relies for priority upon Korean Patent Application No. 2002-965, filed on Jan. 8, 2002, the contents of which are herein incorporated by this reference in their entirety.

### FIELD OF THE INVENTION

The present invention relates to semiconductor devices, more particularly to NAND-type flash memory devices.

### BACKGROUND OF THE INVENTION

A non-volatile memory device retains information stored in its unit cells even when no power is supplied. Nowadays, the non-volatile memory devices are widely used in various kinds of electronic products such as mobile telecommunication systems, memory cards, and so on. Generally, the unit cell of the non-volatile memory device comprises a tunneling layer, a floating gate electrode, an inter-gate dielectric layer and a control gate electrode, which are sequentially stacked on a semiconductor substrate. A representative one of the non-volatile memory devices is a flash memory device, which is classified into either a NAND-type or a NOR-type flash memory device.

In the non-volatile memory device, a coupling ratio CR is an important factor that affects the characteristic of the program or erasure operation thereof. With a higher coupling ratio, the program operation can be performed more rapidly. Moreover, the operating voltage of the program or erasure operation can be decreased by raising coupling ratio. In the case of the NAND-type flash memory device, the program or erasure operation is performed by a FN (Fowler-Nordheim) tunneling, which occurs through a tunneling layer. The FN tunneling occurs when an electric field of 6˜8 MV/cm is induced at the tunneling layer. In other words, a high voltage of 15˜20 V is required to be applied into the control gate electrode. If the coupling ratio is increased, this high voltage can be decreased.

The coupling ratio CR is represented by the following equation:

$$CR = \frac{Cono}{Cono + Ctun}$$

wherein, Cono is a capacitance value of the inter-gate dielectric layer that is formed between the floating gate electrode and the control gate electrode, and Ctun is a capacitance value of the tunneling layer that is formed between the floating gate electrode and the substrate. As shown in the equation, for the purpose of increasing the coupling ratio, the capacitance value Cono needs to be increased, and/or the capacitance value of Ctun needs to be decreased.

FIG. 1 is a schematic plan view illustrating a portion of a cell array area of a conventional NAND-type flash memory device. FIGS. 2 and 3 are cross-sectional views illustrating successive process steps for forming the conventional NAND-type flash memory device. FIGS. 2 and 3 are taken along a line I-I of FIG. 1.

Referring to FIGS. 1 and 2, a plurality of active regions 3 is formed in a semiconductor substrate 1. A tunneling layer 5 and a first conductive layer (not shown in the drawings) are sequentially formed on the substrate 1. The first conductive layer is patterned to form first conductive patterns (not shown in the drawings) that cover the active regions 3. On the resultant structure, an inter-gate dielectric layer 7 and a second conductive layer (not shown in the drawings) are sequentially formed. The second conductive layer, the inter-gate dielectric layer 7 and the first conductive layer patterns are continuously patterned by a photolithographic and etching technique, thereby forming a string selection line pattern, a ground selection line pattern and a plurality of word line patterns.

The string selection line pattern comprises a string selection line SSL, the inter-gate dielectric layer 7 and a dummy string selection line DSSL. The ground selection line pattern comprises a ground selection line GSL, the inter-gate dielectric layer 7 and a dummy ground selection line DGSL. The string selection line patterns and the ground selection line patterns are formed across the active regions 3 in plan view. The plurality of word line patterns comprises a first word line pattern WLP1, intermediate word line patterns and an Nth word line pattern WLPn. The intermediate word line patterns comprise a second word line pattern WLP2, . . . and an N−1th word line pattern WLPn-1. The first word line pattern WLP1 comprises one of the floating gate electrodes FG, the inter-gate dielectric layer 7 and a first word line WL1. In the same way, each of the other word line patterns (i.e., the second, . . . N−1th and Nth word line patterns) comprises a corresponding one of the floating gate electrodes FG, the inter-gate dielectric layer 7 and a corresponding one of the other word lines (i.e., WL2, . . . WLn-1, WLn). The word lines (i.e., WL1, WL2, . . . WLn-1, WLn) act as control gate electrodes in device operation. Each of the floating gate electrodes FG is located at one of the intersections between the word lines and the active regions 3. The plurality of word line patterns is disposed between the string selection line patterns and the ground selection line patterns in plan view. The plurality of word line patterns is disposed parallel to the string selection line patterns and the ground selection line patterns.

The plurality of word lines is equally spaced. In other words, the distance between each of the word lines and the adjacent one of the word lines is approximately the same distance S2. Each of the plurality of word line patterns has approximately the same width WW. The width WS of the string selection line pattern is greater than the width WW of the word line patterns. The width WG of the ground selection line pattern is greater than the width WW of the word line patterns.

The distance S1′ between the string selection line pattern and the first word line pattern WLP1 and the distance S1″ between the ground selection line pattern and the Nth word line pattern WLPn are adjusted to be greater that the distance S2 between the word line patterns. This is because the string or ground selection line patterns may have an abnormal profile due to a well-known proximity effect and loading effect if the distances S1′ and S1″ are approximately same as the distance S2.

During the etching for the patterning of the second conductive layer, the inter-gate dielectric layer 7 and the first conductive layer patterns, the tunneling layer 5 may be over-etched, so that a portion of the substrate 1 is exposed, as shown, and etch damage is induced on the substrate 1.

Referring to the FIG. 3, the resultant structure is subjected to thermal oxidation to relieve the etch damage induced by the etching for the patterning of the second conductive layer, the inter-gate dielectric layer 7 and the first conductive layer patterns, thereby forming a thermal oxide 9 on the surface of the resultant structure. It is well known that the thermal oxide 9 is also formed on a portion of the top and bottom surface of the tunneling layer 5 and the inter-gate dielectric layer 7, thereby forming so called ‘bird's beaks’ at the edge portion of the tunneling layer 5 and the inter-gate dielectric layer 5. In general, the bird's beaks at the edge portion of the inter-gate dielectric layer 7 are thicker that the bird's beaks at the edge portion of the tunneling layer 5. This is because the inter-gate dielectric layer 7 is usually formed of an ONO (Oxide-nitride-oxide) layer, which comprises a nitride layer between a lower oxide layer and an upper oxide layer. Oxygen can easily penetrate and flow into the top and bottom surface of the nitride layer.

As described above, the distance S1′ is greater than the distance S2. This means that the amount of oxygen that is supplied into the space between the string selection line pattern and the first word line pattern WLP1 is greater than the amount of the oxygen that is supplied into the space between the word line patterns. Therefore, one skilled in the art would recognize that the bird beaks designated by reference symbol A of the first word line pattern WLP1 are abnormally greater than the bird beaks of the intermediate word line patterns. That is to say, the total equivalent thickness of the inter-gate dielectric layer 7 of the first word line pattern WLP1 is greater than those of the intermediate word line patterns. The total equivalent thickness is a value deduced by electrically measuring the capacitance value between corresponding pair of floating gate electrodes FG and word lines.

Similarly, the bird beaks designated by reference symbol A of the Nth word line pattern WLPn are also greater than the bird beaks of the intermediate word line patterns, and a total equivalent thickness of the inter-gate dielectric layer 7 of the Nth word line pattern WLPn is greater than the thicknesses of the intermediate word line patterns.

As a result, the coupling ratios of the first word line pattern WLP1 and the Nth word line pattern WLPn are less than those of the intermediate word line patterns. The lower coupling ratio means that the time for program operation is unfavorably long. Consequently, the uniformities of coupling ratio and programming time of the device are poor, and average programming time is high.

Meanwhile, under certain conditions, the bird beaks of the tunneling layer 5 of the first word line pattern WLP1 and the Nth word line pattern WLPn may also be abnormally greater than those of the intermediate word line patterns. In this case, efficiency of the program and erasure operations is poor due to the thick tunneling layer, even though the coupling ratio of the first word line pattern WLP1 and the Nth word line pattern WLPn may be relatively high.

### SUMMARY OF THE INVENTION

It is an object of the present invention to provide a semiconductor device having an improved uniformity of coupling ratio.

It is another object of the present invention to provide a non-volatile memory device having improved uniformity of programming time.

It is another object of the present invention to provide a flash memory device having improved uniformities of coupling ratio and programming time.

According to one aspect of the present invention, a semiconductor device is provided. The semiconductor device comprises a substrate and a plurality of active regions in the substrate. A ground selection line is formed on the substrate. The ground selection line is disposed across the plurality of active regions. A string selection line is formed on the substrate. The string selection line is disposed parallel to the ground selection line. A plurality of word lines is formed on the substrate. The plurality of word lines is disposed parallel to the ground selection line. The plurality of word lines is disposed between the ground selection line and the string selection line in plan view. The plurality of word lines comprises a first selected word line and a plurality of intermediate word lines. The first selected word line is wider than the plurality of intermediate word lines.

According to another aspect of the present invention, a semiconductor device is provided. The semiconductor device comprises a substrate having a plurality of active regions. A ground selection line pattern is formed on the substrate. The ground selection line is disposed across the plurality of active regions. A string selection line pattern is formed on the substrate. The string selection line pattern is disposed parallel to the ground selection line pattern. Word line patterns are formed on the substrate. The total number of the word line patterns is N. The word line patterns are disposed parallel to the string selection line pattern. The plurality of word line patterns is disposed between the ground selection line pattern and the string selection line pattern in plan view. The plurality of word line patterns comprises a first word line pattern and a Nth word line pattern. The first word line pattern is adjacent to the string selection line pattern. The Nth word line pattern is adjacent to the ground selection line pattern. Intermediate word line patterns are disposed between the first and Nth word line patterns in plan view. The Nth word line pattern is wider than the intermediate word line patterns.

### BRIEF DESCRIPTION OF THE DRAWINGS

Other features of the present invention will be more readily understood from the following detail description of specific embodiment thereof when read in conjunction with the accompanying drawings, in which:

FIG. 1 is a schematic plan view illustrating a portion of a cell array area of a conventional NAND-type flash memory device;

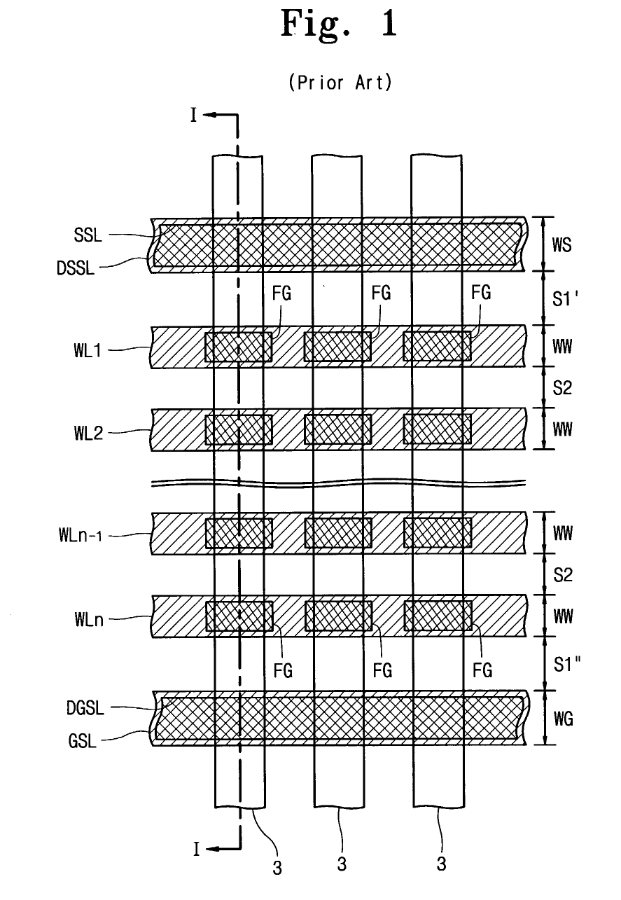

FIGS. 2 and 3 are cross-sectional views illustrating successive process steps for forming the conventional NAND-type flash memory device;

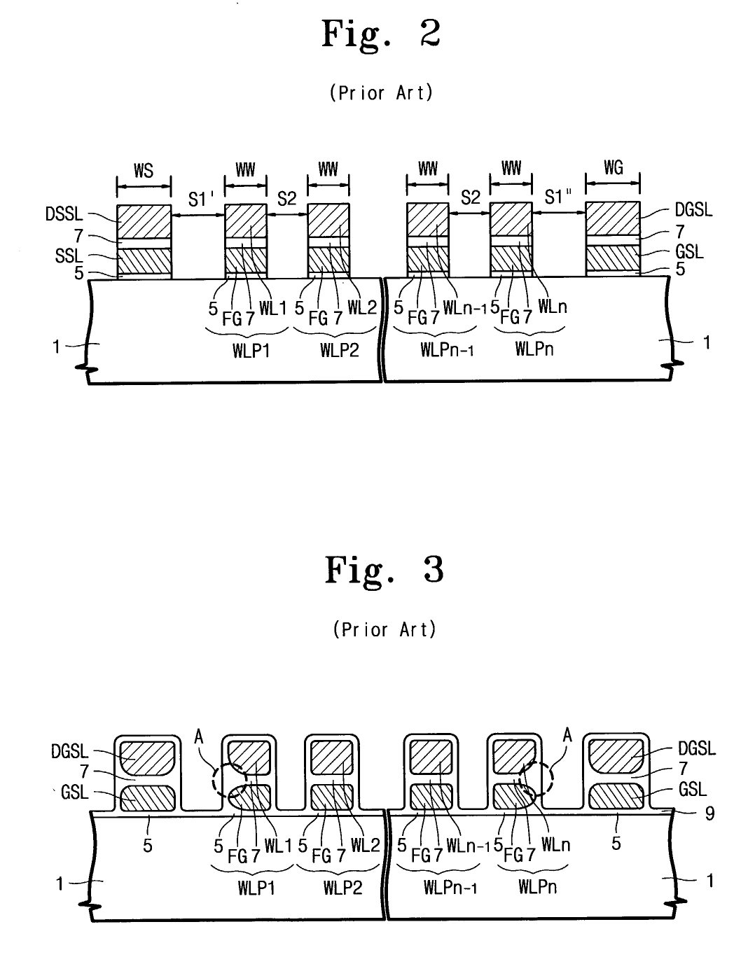

FIG. 4 is a schematic plan view illustrating a preferred embodiment of a portion of a cell array area of a NAND-type flash memory device according to the present invention; and

FIGS. 5 and 6 are cross-sectional views illustrating successive process steps for forming the NAND-type flash memory device according to the present invention.

### DESCRIPTION OF THE PREFERRED EMBODIMENT

Preferred embodiments of the present invention will be described hereinafter with reference to the accompanying drawings, even though the scope of the present invention is not limited to the embodiments. Rather, these embodiments are provided so that this disclosure will be thorough and complete, and will fully convey the scope of the invention to those skilled in the art. In attached figures, the thickness of layers and regions is exaggerated for clarity. Also, when it is mentioned that a layer is on another layer or on a substrate, a layer can be directly formed on another layer or on a substrate, or the third layer can be interposed therebetween. The same reference numbers indicate the same components throughout the whole specifications.

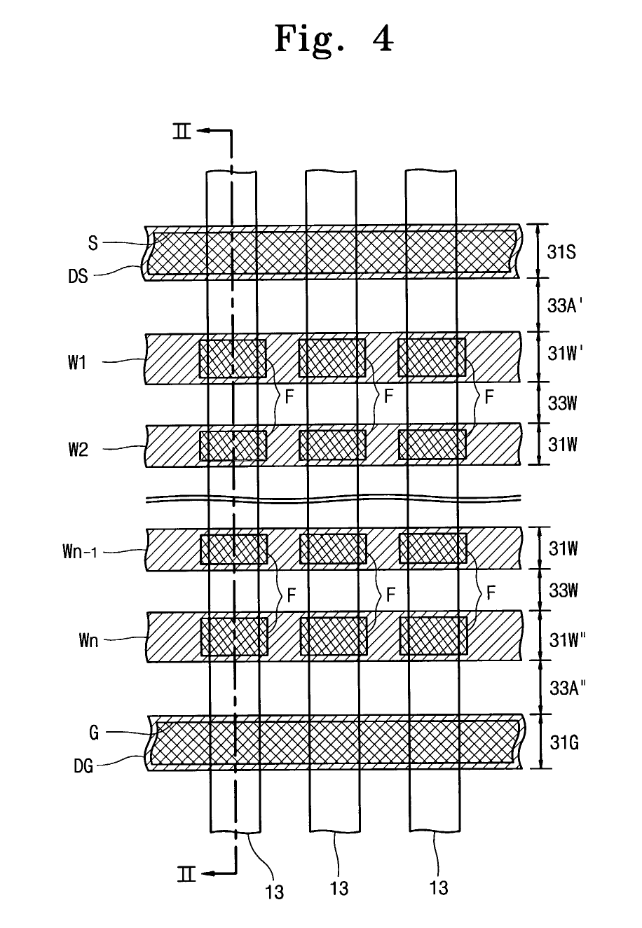

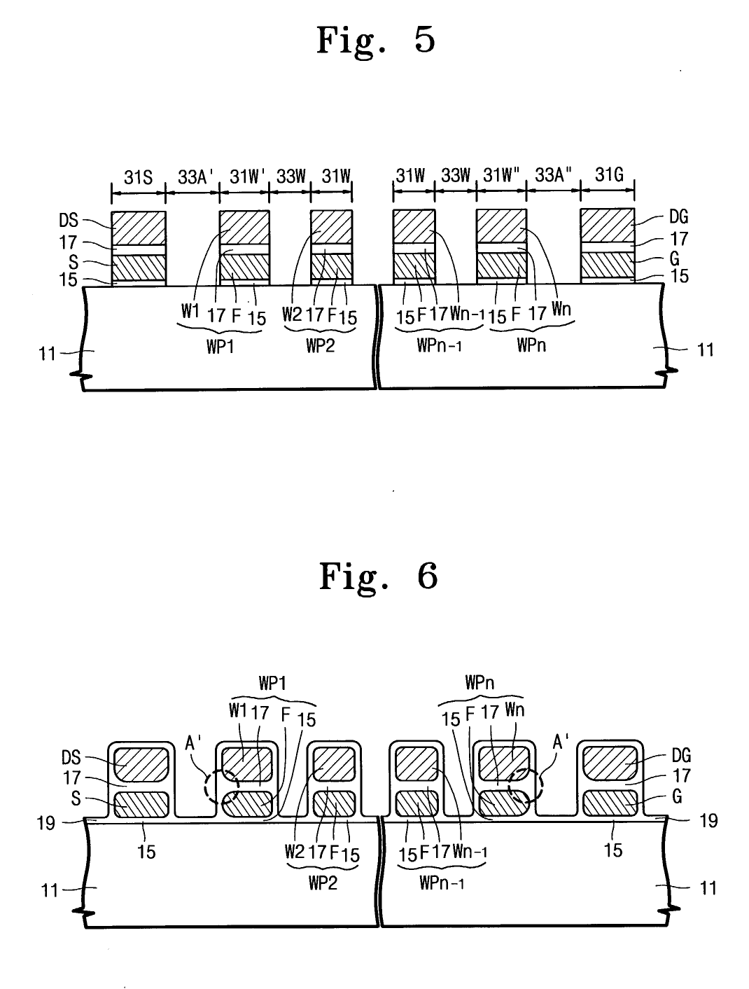

FIG. 4 is a schematic plan view illustrating a preferred embodiment of a portion of a cell array area of a NAND-type flash memory device according to the present invention. FIGS. 5 and 6 are cross-sectional views illustrating successive process steps for forming the NAND-type flash memory device according to the present invention. FIGS. 5 and 6 are taken along a line II-II of FIG. 4.

Referring to FIGS. 4 and 5, a plurality of active regions 13 is defined in a semiconductor substrate 11 by forming an isolation region (not shown in the drawings). The active regions 13 are disposed parallel to each other as shown in FIG. 4. A tunneling layer 15 and a first conductive layer (not shown in the drawings) is sequentially formed on the substrate 11. The first conductive layer is preferably a doped polysilicon layer. The first conductive layer is patterned to form first conductive patterns (not shown in the drawings) that cover the active regions 13. On the resultant structure, an inter-gate dielectric layer 17 and a second conductive layer (not shown in the drawings) are sequentially formed. The inter-gate dielectric layer 17 is preferably an ONO (Oxide-nitride-oxide) layer comprising a nitride layer between a lower oxide layer and an upper oxide layer. The inter-gate dielectric layer 17 alternatively can be a tantalum oxide layer or silicon oxide layer. The second conductive layer is preferably a doped polysilicon layer or a polycide layer.

The second conductive layer, the inter-gate dielectric layer 7 and the first conductive layer patterns are continuously patterned by a photolithographic and etching technique, thereby forming a string selection line pattern, a ground selection line pattern and a plurality of word line patterns, all disposed across the active regions 13. During the etching for the patterning of the second conductive layer, the inter-gate dielectric layer 17 and the first conductive layer patterns, the tunneling layer 15 often is undesirably over-etched, so that a portion of the substrate 11 is exposed, and an etch damage is induced on the substrate 11.

The string selection line pattern comprises a string selection line S, the inter-gate dielectric layer 17 and a dummy string selection line DS. The ground selection line pattern comprises a ground selection line G, the inter-gate dielectric layer 17 and a dummy ground selection line DG. The string selection line patterns and the ground selection line patterns are formed across the active regions 13 in plan view. The plurality of word line patterns comprises a first word line pattern WP1, intermediate word line patterns and an Nth word line pattern WPn. The intermediate word line patterns comprise a second word line pattern WP2, . . . and an N−1th word line pattern WPn-1. The first word line pattern WP1 comprises one of the floating gate electrodes F, the inter-gate dielectric layer 17 and a first word line W1. In the same way, each of the other word line patterns (i.e., the second, . . . N−1th and Nth word line patterns) comprises a corresponding one of the floating gate electrodes F, the inter-gate dielectric layer 17 and a corresponding one of the other word lines (i.e., W2, . . . Wn-1, Wn). The word lines act as control gate electrodes in the device operation. Each of the floating gate electrodes F is located at one of intersections between the word lines and the active regions 13.

The plurality of word line patterns is disposed between the string selection line patterns and the ground selection line patterns in plan view. The plurality of word line patterns is disposed parallel to the string selection line patterns and the ground selection line patterns. The word line patterns are disposed parallel to each other. The dummy string selection line DS, the dummy ground selection line DG and the word lines are formed of the second conductive layer. The string selection line S, the ground selection line G and the floating gate electrodes F are formed of the first conductive pattern.

The plurality of word lines is equally spaced. In other words, the distance between each pair of adjacent word lines is approximately the same distance 33W. Each of the intermediate word line patterns (i.e., WP2, . . . WPn-1) has approximately the same width 31W. The width 31S of the string selection line pattern is greater than the width 31W of the intermediate word line patterns. The width 31G of the ground selection line pattern is greater than the width 31W of the intermediate word line patterns. The width 31S of the string selection line pattern and the width 31G of the ground selection line pattern are approximately the same.

The distance 33A′ between the string selection line pattern and the first word line pattern WP1 and the distance 33A″ between the ground selection line pattern and the Nth word line pattern WPn are greater than the distance 33W between the intermediate word line patterns.

In contrast to the conventional device, the width 31W′ of the first word line pattern is greater than the width 31W of the intermediate word line patterns, and the width 31W″ of the Nth word line pattern is also greater than the width 31W of the intermediate word line patterns. Preferably, each of the widths 31W′ and 31W″ are 105˜120% of the width 31W. The width 31W″ of the Nth word line pattern is approximately the same as the width 31W′ of the first word line pattern.

In a modified version of this embodiment of the present invention, between the string selection line S and substrate 11, a gate dielectric layer may intervene instead of the tunneling layer 15 by a well-known method. Similarly, between the ground selection line G and substrate 11, the gate dielectric layer may intervene instead of the tunneling layer 15. Moreover, the string selection line pattern may comprise only the string selection line S by a well-known method. Similarly, the ground selection line pattern may comprise only the ground selection line G. And, the width 31W″ of the Nth word line pattern may be greater than the width 31W′ of the first word line pattern.

Referring to FIG. 6, the resultant structure is subjected to thermal oxidation to relieve the etch damage induced by the etching for the patterning of the second conductive layer, the inter-gate dielectric layer 17 and the first conductive layer patterns, thereby forming a thermal oxide 19 on the surface of the resultant structure.

The thermal oxidation also results in forming bird's beaks at the edge portion of the tunneling layer 15 and the inter-gate dielectric layer 17. The bird beaks designated by reference symbol A′ of the first and the Nth word line pattern WP1, WPn are greater than the bird beaks of the intermediate word line patterns, as shown in FIG. 6.

However, the total equivalent thicknesses of the inter-gate dielectric layer 17 of the first and the Nth word line patterns WP1, WPn are less than those of the first and the Nth word line patterns WLP1, WLPn of the conventional device. That is to say, the coupling ratios of the first and Nth word line patterns WP1, WPn are greater than those of the first and the Nth word line patterns WLP1, WLPn of the conventional device. This is because the width 31W′ and the width 31W″ are greater than the width 31W, which represents an important difference from the conventional device. In other words, the uniformities of coupling ratio and programming time are improved by increasing the widths of the first and Nth word line patterns WP1, WPn compared to the conventional device.

In the drawings and specification, there have been disclosed typical preferred embodiments of the invention and, although specific terms are employed, they are used in a generic and descriptive sense only and not for purpose of limitation, the scope of the invention being set forth in the following claims.

What is claimed is:

1. A semiconductor device comprising:
a substrate;
a plurality of active regions in the substrate;
a ground selection line formed on the substrate, wherein the ground selection line is disposed across the plurality of active regions;
a string selection line formed on the substrate, wherein the string selection line is disposed parallel to the ground selection line; and
a plurality of word lines formed on the substrate, wherein the plurality of word lines is disposed parallel to the ground selection line, wherein the plurality of word lines is disposed between the ground selection line and the string selection line in plan view, and wherein the plurality of word lines comprises:
a first selected word line; and
a plurality of intermediate word lines, wherein the first selected word line is wider than each of the plurality of intermediate word lines.

2. The semiconductor device of claim 1, wherein the selected word line is disposed between the ground selection line and the plurality of intermediate word lines.

3. The semiconductor device of claim 2, wherein the distance between the ground selection line and the first selected word line is greater than the distances between the word lines.

4. The semiconductor device of claim 1, wherein the selected word line is disposed between the string selection line and the plurality of intermediate word lines.

5. The semiconductor device of claim 4, wherein the distance between the string selection line and the first selected word line is greater than the distances between the word lines.

6. The semiconductor device of claim 1, wherein the plurality of word lines further comprises a second selected word line, wherein the second selected word line is wider than the plurality of intermediate word lines in their widths.

7. The semiconductor device of claim 6, wherein the plurality of intermediate word lines is disposed between the first selected word line and the second selected word line in plan view.

8. The semiconductor device of claim 6, wherein the first and second selected word lines have approximately the same width.

9. The semiconductor device of claim 6, wherein the first selected word line is wider than the second selected word line.

10. The semiconductor device of claim 1, wherein each of the plurality of intermediate word lines has approximately the same width.

11. The semiconductor device of claim 1, wherein the distance between each pair of adjacent word lines is approximately the same.

12. A semiconductor device comprising:
a substrate;
a plurality of active regions in the substrate;
a ground selection line pattern formed on the substrate, wherein the ground selection line is disposed across the plurality of active regions;
a string selection line pattern formed on the substrate, wherein the string selection line pattern is disposed parallel to the ground selection line pattern; and
a plurality of word line patterns formed on the substrate, wherein the total number of the word line patterns is N, wherein the word line patterns is disposed parallel to the string selection line pattern, wherein the plurality of word line patterns is disposed between the ground selection line pattern and the string selection line pattern in plan view, and wherein the plurality of word line patterns comprises:
a first word line pattern that is adjacent to the string selection line pattern;
a Nth word line pattern that is adjacent to the ground selection line pattern; and intermediate word line patterns disposed between the first and Nth word line patterns in plan view;
wherein the Nth word line pattern is wider than the intermediate word line patterns.

13. The semiconductor device of claim 12, wherein the first word line pattern is wider than each of the intermediate word line patterns.

14. The semiconductor device of claim 12, wherein the distance between the ground selection line pattern and the Nth word line pattern is greater than the distance between each pair of adjacent intermediate word line patterns.

15. The semiconductor device of claim 12, wherein the distance between the string selection line pattern and the first word line pattern is greater than the distance between each pair of adjacent intermediate word line patterns.

16. The semiconductor device of claim 12, wherein the first and Nth word line patterns have approximately the same width.

17. The semiconductor device of claim 12, wherein the Nth word line pattern is wider than the first word line pattern.

18. The semiconductor device of claim 12, wherein each of the intermediate word line patterns has approximately the same width.

19. The semiconductor device of claim 12, wherein the distance between each pair of adjacent word line patterns is approximately the same.

20. The semiconductor device of claim 12, wherein the string selection line pattern is wider than each of the intermediate word line patterns.

21. The semiconductor device of claim 12, wherein the ground selection line pattern is wider than each of the intermediate word line patterns.

22. The semiconductor device of claim 12, wherein the ground selection line pattern comprises:
a ground selection line formed on the substrate;
an inter-gate dielectric layer formed on the ground selection line; and
a dummy ground selection line formed on the inter-gate dielectric layer.

23. The semiconductor device of claim 12, wherein the string selection line pattern comprises:
a string selection line formed on the substrate;
an inter-gate dielectric layer formed on the string selection line; and
a dummy string selection line formed on the inter-gate dielectric layer.

24. The semiconductor device of claim 12, wherein each of the word line patterns comprises:
a floating gate electrode on the substrate;
an inter-gate dielectric layer formed on the floating gate electrode; and
a control gate electrode formed on the inter-gate dielectric layer;
wherein the floating gate electrode intervenes only between the control gate electrode and the plurality of active regions.
